(19) United States
(12) Patent Application Publication
(10) Pub. No.: US 2024/0052222 A1
(43) Pub. Date: Feb. 15, 2024

(54) POLISHING LIQUID, POLISHING LIQUID SET AND POLISHING METHOD

(71) Applicant: RESONAC CORPORATION, Minato, Tokyo (JP)

(72) Inventors: Daisuke IIKURA, Tokyo (JP); Masako AOKI, Tokyo (JP)

(21) Appl. No.: 18/264,534

(22) PCT Filed: Apr. 20, 2021
(86) PCT No.: PCT/JP2021/016064

§ 371 Date: Aug. 7, 2023

(51) Int. Cl. C09K 3/14; C09K 13/06

(52) U.S. Cl. CPC C09K 3/1463; C09K 3/1409; C09K 13/06

(57) ABSTRACT

A polishing liquid containing abrasive grains including a hydroxide of a tetravalent metal element, a polymer including a structure unit represented by Formula (1) below, and a liquid medium.

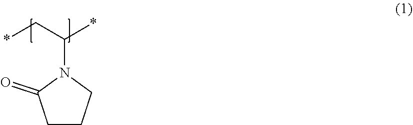

[in Formula (1), * represents a bonding hand.]

### TECHNICAL FIELD

The present invention relates to a polishing liquid, a polishing liquid set, and a polishing method.

### BACKGROUND ART

In the manufacturing steps for semiconductor elements in recent years, the importance of processing technologies for density increase and micronization is increasing more and more. CMIP (Chemical mechanical polishing) technology, which is one of the processing technologies, has become an essential technology for formation of a shallow trench isolation (hereinafter, referred to as “STI”), flattening of a pre-metal insulating material or an interlayer insulating material, formation of a plug or an embedded metal wiring, or the like in the manufacturing steps for semiconductor elements.

In the manufacturing steps for semiconductor elements in recent years, it is required to achieve further micronization of processing dimensions, and in this connection, polishing scratches generated during polishing by CIP are becoming problematic. With regard to this problem, an investigation has been conducted on polishing liquids that use hydroxide particles of a tetravalent metal element (see, for example, Patent Literature 1 below). This technology is directed to reduce polishing scratches caused by particles, by making the mechanical action as small as possible while utilizing the chemical action of the hydroxide particles of a tetravalent metal element.

Furthermore, for the micronization of processing dimensions, for example, in the formation of STI or the like, a stopper (a polishing stop portion formed using a stopper material) is used as one of means for stopping polishing at a predetermined position in some cases. In an example of CMP using a stopper, a part of a portion to be polished of an article (article to be polished), which has a base material having a concavo-convex pattern (for example, an element isolation structure), a stopper disposed on the convex portion of the base material, and a portion to be polished (for example, an insulating portion formed using an insulating material) disposed on the base material and the stopper to fill the concave portion of the base material, is polished until the stopper is exposed. Thereby, it becomes easy to suppress the polishing amount of the portion to be polished.

### CITATION LIST

### Patent Literature

Patent Literature 1: International Publication WO 2012/070544

### SUMMARY OF INVENTION

### Technical Problem

In the formation of STI, generally, an article having silicon oxide (SiO₂) as an insulating material and silicon nitride (SiN) as a stopper material is used as an article to be polished. In such an article, in recent years, with micronization of semiconductor elements, attempts to further narrow the pitch (for example, element isolation width) of the concavo-convex pattern are increasing. In the conventional polishing liquid using the hydroxide particles of a tetravalent metal element, the stopper on the narrow-width portion is over-polished (eroded), so that sufficient element isolation cannot be achieved. Furthermore, with micronization of semiconductor elements in recent years, since the thickness reduction of the stopper has proceeded, it is necessary to further suppress over-polishing of the stopper.

In this regard, an object of the present invention is to provide a polishing liquid capable of suppressing over-polishing of a stopper while having a sufficient polishing rate with respect to silicon oxide in polishing of an article which has a base material having a concavo-convex pattern with a narrow pitch width, a stopper disposed on the convex portion of the base material and containing silicon nitride, and a portion to be polished disposed on the base material and the stopper to fill the concave portion of the base material and containing silicon oxide.

### Solution to Problem

An aspect of the present invention relates to a polishing liquid containing abrasive grains including a hydroxide of a tetravalent metal element, a polymer including a structure unit represented by Formula (1) below, and a liquid medium.

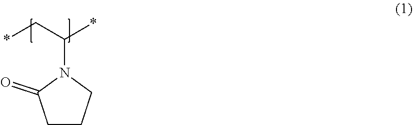

[in Formula (1), * represents a bonding hand.]

According to the polishing liquid of the aspect, over-polishing of the stopper containing silicon nitride can be suppressed while a portion to be polished containing silicon oxide is polished at a sufficient polishing rate. In particular, in polishing of an article which has a base material having a concavo-convex pattern with a narrow pitch width, a stopper disposed on the convex portion of the base material and containing silicon nitride, and a portion to be polished disposed on the base material and the stopper to fill the concave portion of the base material and containing silicon oxide, over-polishing of the stopper can be suppressed while a sufficient polishing rate with respect to silicon oxide is achieved.

In an embodiment, the polymer may further include a structure unit derived from a (meth)acrylic acid ester. The structure unit derived from a (meth)acrylic acid ester may be a structure unit represented by Formula (2) below.

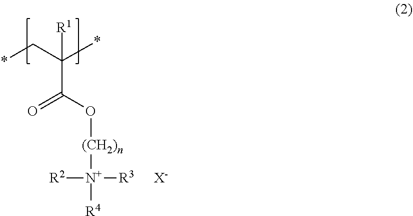

[in Formula (2), R¹ represents a hydrogen atom or a methyl group, R² to R⁴ each independently represent a hydrocarbon group having 1 to 4 carbon atoms, n represents an integer of 1 or more and 4 or less, X⁻ represents a counter anion, and * represents a bonding hand.]

In the embodiment, a weight average molecular weight of the polymer may be 50000 or more.

In the embodiment, the hydroxide of a tetravalent metal element may be cerium hydroxide.

In the embodiment, a pH of the polishing liquid may be 3.0 to 5.0.

In the embodiment, the polishing liquid may be a polishing liquid used for selectively polishing silicon oxide with respect to silicon nitride.

Another aspect of the present invention relates to a polishing liquid set containing constituent components of the above-described polishing liquid separately stored as a first liquid and a second liquid, the first liquid containing the abrasive grains and a liquid medium, the second liquid containing the polymer and a liquid medium. According to this polishing liquid set, the above-described polishing liquid is obtained by mixing the first liquid and the second liquid.

Still another aspect of the present invention relates to a polishing method including a step of preparing an article, the article having a base material having a concavo-convex pattern, a stopper disposed on the convex portion of the base material and containing silicon nitride, and a portion to be polished disposed on the base material and the stopper to fill the concave portion of the base material and containing silicon oxide, and a step of polishing a part of the portion to be polished by using the above-described polishing liquid or a polishing liquid obtained by mixing the first liquid and the second liquid of the above-described polishing liquid set. According to this method, generation of polishing scratches due to over-polishing of the stopper can be suppressed while the portion to be polished containing silicon oxide is polished at a sufficient polishing rate.

### Advantageous Effects of Invention

According to the present invention, it is possible to provide a polishing liquid capable of suppressing over-polishing of a stopper while having a sufficient polishing rate with respect to silicon oxide in polishing of an article which has a base material having a concavo-convex pattern with a narrow pitch width, a stopper disposed on the convex portion of the base material and containing silicon nitride, and a portion to be polished disposed on the base material and the stopper to fill the concave portion of the base material and containing silicon oxide.

### BRIEF DESCRIPTION OF DRAWINGS

FIG. 1 is a schematic cross-sectional view illustrating an embodiment of a polishing method of the present invention.

FIG. 2 is a schematic cross-sectional view illustrating a pattern wafer before and after an erosion evaluation of Examples.

### DESCRIPTION OF EMBODIMENTS

Hereinafter, preferred embodiments of the present invention will be described. However, the present invention is not limited to the following embodiments at all.

Note that, in the present specification, a numerical range that has been indicated by use of “to” indicates the range that includes the numerical values which are described before and after “to”, as the minimum value and the maximum value, respectively. In the numerical ranges that are described stepwise in the present specification, the upper limit value or the lower limit value of the numerical range of a certain stage may be replaced with the upper limit value or the lower limit value of the numerical range of another stage.

In the numerical ranges that are described in the present specification, the upper limit value or the lower limit value of the numerical range may be replaced with the value shown in Examples. Furthermore, “A or B” in the present specification may include either one of A and B, and may also include both of A and B. Materials listed as examples in the present specification can be used singly or in combinations of two or more kinds, unless otherwise specified. In the present specification, when a plurality of substances corresponding to each component exist in the composition, the content of each component in the composition means the total amount of the plurality of substances that exist in the composition, unless otherwise specified.

<Polishing liquid>

A polishing liquid of an embodiment contains abrasive grains including a hydroxide of a tetravalent metal element, a polymer including a structure unit represented by Formula (1) below, and a liquid medium.

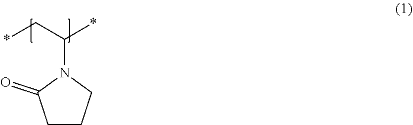

[in Formula (1), * represents a bonding hand.]

The above-described polishing liquid is, for example, a polishing liquid for CMP, and is suitably used for selectively polishing silicon oxide with respect to silicon nitride. Specifically, for example, the polishing liquid is suitably used for polishing a portion to be polished of an article (article to be polished) to expose a stopper, the article having a base material having a concavo-convex pattern (for example, an element isolation structure), a stopper disposed on the convex portion of the base material and containing silicon nitride, and a portion to be polished disposed on the base material and the stopper to fill the concave portion of the base material and containing silicon oxide.

According to the above-described polishing liquid, over-polishing of the stopper containing silicon nitride can be suppressed while a surface to be polished containing silicon oxide is polished at a sufficient polishing rate. In particular, in a case where the base material constituting the above-described article has a concavo-convex pattern with a narrow pitch width (width of line/space (L/S)), such an effect becomes significant. Therefore, according to the above-described polishing liquid, it is possible to obtain an article in which the pitch width (width of line/space (L/S)) of a pattern defined by a portion to be polished containing silicon oxide and a stopper containing silicon nitride is narrow and over-polishing of the stopper is reduced. Furthermore, according to the above-described polishing liquid, since the polishing rate for silicon nitride can be suppressed, there is a tendency that a high polishing selectivity (a ratio of the polishing rate for silicon oxide with respect to the polishing rate for silicon nitride, the polishing rate for silicon oxide/the polishing rate for silicon nitride) is obtainable.

(Abrasive Grains)

The abrasive grains include a hydroxide of a tetravalent metal element. The “hydroxide of a tetravalent metal element” is a compound including a tetravalent metal ion (M⁴⁺) and at least one hydroxide ion (OH⁻). The hydroxide of a tetravalent metal element may also include an anion other than a hydroxide ion (for example, a nitrate ion NO₃⁻ and a sulfate ion SO₄²⁻). For example, the hydroxide of a tetravalent metal element preferably includes an anion which is bonded to a tetravalent metal element (excluding a hydroxide ion; for example, a nitrate ion NO³⁻ and a sulfate ion SO₄²⁻) and more preferably includes a nitrate ion which is bonded to a tetravalent metal element, from the viewpoint of further improving the polishing rate for a material to be removed (for example, an insulating material such as silicon oxide).

The hydroxide of a tetravalent metal element can be prepared by reacting a salt of a tetravalent metal element (metal salt) with an alkali source (base). It is preferable that the hydroxide of a tetravalent metal element is prepared by mixing a salt of a tetravalent metal element with an alkali solution (for example, an alkali aqueous solution). Thereby, particles having a very fine particle diameter can be obtained, and a polishing liquid having a further excellent effect of reducing polishing scratches can be obtained. Such a technique is disclosed in, for example, Patent Literature 1 described above. The hydroxide of a tetravalent metal element can be obtained by mixing a metal salt solution including a salt of a tetravalent metal element (for example, a metal salt aqueous solution) with an alkali solution. As the salt of a tetravalent metal element, those conventionally known can be used. Examples thereof include M(NO₃)₄, M(SO₄)₂, M(NH₄)₂(NO₃)₆, M(NH₄)₄(SO₄)₄ (wherein M represents a rare earth element), and Zr(SO₄)₂·4H₂O. Cerium (Ce) which is chemically active is preferable for M.

The content of the abrasive grains is preferably in the following range on the basis of the total mass of the polishing liquid. The content of the abrasive grains is preferably 0.005% by mass or more, more preferably 0.01% by mass or more, further preferably 0.02% by mass or more, particularly preferably 0.03% by mass or more, extremely preferably 0.04% by mass or more, and highly preferably 0.05% by mass or more, from the viewpoint of easily exhibiting the function of the hydroxide of a tetravalent metal element sufficiently. The content of the abrasive grains is preferably 20% by mass or less, more preferably 10% by mass or less, even more preferably 5% by mass or less, particularly preferably 3% by mass or less, extremely preferably 1% by mass or less, highly preferably 0.5% by mass or less, still even more preferably 0.3% by mass or less, and especially preferably 0.1% by mass or less, from the viewpoints of easily avoiding the aggregation of the abrasive grains, easily obtaining favorable chemical interaction with a surface to be polished, and easily utilizing the properties of the abrasive grains effectively. From these viewpoints, the content of the abrasive grains is preferably 0.005 to 20% by mass.

In a case where the average particle diameter (average secondary particle diameter) of the abrasive grains is small to some extent, the specific surface area of the abrasive grains that are in contact with the surface to be polished is increased, and thus the polishing rate for a material to be removed (for example, an insulating material) can be further improved and the mechanical action is suppressed so that polishing scratches can be further reduced. Therefore, the average particle diameter of the abrasive grains including the hydroxide of a tetravalent metal element is preferably 300 nm or less, more preferably 200 nm or less, even more preferably 150 nm or less, particularly preferably 100 nm or less, extremely preferably 80 nm or less, highly preferably 60 nm or less, still even more preferably 40 nm or less, more preferably 20 nm or less, and further preferably 10 nm or less, from the viewpoints of obtaining a further excellent polishing rate for a material to be removed (for example, an insulating material) and further reducing polishing scratches. The average particle diameter of the abrasive grains including the hydroxide of a tetravalent metal element is preferably 1 nm or more and more preferably 2 nm or more, from the viewpoints of obtaining a further excellent polishing rate for a material to be removed (for example, an insulating material) and further reducing polishing scratches. From these viewpoints, the average particle diameter of the abrasive grains including the hydroxide of a tetravalent metal element is preferably 1 to 300 nm.

The “average particle diameter” of the abrasive grains means an average secondary particle diameter of the abrasive grains in the polishing liquid. The average particle diameter of the abrasive grains can be measured by using an optical diffraction scattering particle size distribution meter (for example, manufactured by Beckman Coulter, Inc., trade name: DelsaMax PRO). In the measurement method using trade name: DelsaMax PRO manufactured by Beckman Coulter, Inc., specifically, for example, about 0.5 mL (L represents “liter”; the same applies hereinafter) of the polishing liquid is placed in a cell for measurement having a size of 12.5 mm×12.5 mm×45 mm (height) and then the cell is installed in the apparatus. Measurement is performed at 25° C. with the refractive index set to 1.333 and the viscosity set to 0.887 mPa-s as the measurement sample information, and the value displayed as Unimodal Size Mean (cumulant diameter) can be adopted as the average particle diameter of the abrasive grains.

The polishing liquid preferably has high transparency for visible light (visually transparent or nearly transparent). Specifically, it is preferable that the abrasive grains contained in the polishing liquid provide a light transmittance of 50%/cm or more for light having a wavelength of 500 nm in an aqueous dispersion liquid in which the content of the abrasive grains is adjusted to 1.0% by mass. Thereby, a decrease in the polishing rate for a material to be removed (for example, an insulating material) due to the addition of an additive can be further suppressed, and thus, it becomes easy to obtain other properties while maintaining the polishing rate. From the same viewpoints, the light transmittance is more preferably 60%/cm or more, further preferably 70%/cm or more, particularly preferably 80%/cm or more, extremely preferably 90%/cm or more, and highly preferably 92%/cm or more. The upper limit of the light transmittance is 100%/cm.

The reason why the decrease in the polishing rate for a material to be removed (for example, an insulating material) can be suppressed by adjusting the light transmittance of the abrasive grains in this manner is not understood in detail, but it is considered that the action of the abrasive grains including the hydroxide of a tetravalent metal element (for example, cerium), as abrasive grains, is more dominantly dependent on the chemical action than on the mechanical action. Therefore, it is considered that the number of abrasive grains contributes to the polishing rate rather than the size of the abrasive grains.

In a case where the light transmittance of the aqueous dispersion liquid in which the content of the abrasive grains is adjusted to 1.0% by mass is low, it is considered that the abrasive grains present in the aqueous dispersion liquid include a relatively larger portion of particles having a large particle diameter (hereinafter, referred to as “coarse particles”). When an additive is added to the polishing liquid containing such abrasive grains, coarse particles serve as nuclei, and other particles aggregate around thereon. As a result, it is considered that, since the number of abrasive grains acting on the surface to be polished per unit area (effective number of abrasive grains) is reduced, and the specific surface area of the abrasive grains that are in contact with the surface to be polished is reduced, the polishing rate is decreased.

On the other hand, in a case where the light transmittance in an aqueous dispersion liquid in which the content of the abrasive grains is adjusted to 1.0% by mass is high, it is considered that the abrasive grains present in the aqueous dispersion liquid are in a state in which there are few “coarse particles” described above. In a case where the abundance of coarse particles is small like this, even if an additive is added to the polishing liquid, since there are few coarse particles that become the nuclei of aggregation, aggregation between abrasive grains is suppressed, or the size of the aggregated particles is relatively small. As a result, it is considered that, since the number of abrasive grains acting on the surface to be polished per unit area (effective number of abrasive grains) is maintained, and the specific surface area of the abrasive grains that are in contact with the surface to be polished is maintained, the polishing rate is difficult to decrease.

It can be seen from the studies in the past that, even for polishing liquids having the same particle diameter of the abrasive grains measured with a general particle diameter measuring apparatus, there may be a polishing liquid that is visually transparent (the light transmittance is high) and a polishing liquid that is visually cloudy (the light transmittance is low). According to this, it is considered that coarse particles that can cause such action as described above contribute to a decrease in the polishing rate even with a very small amount that is undetectable with a general particle diameter measuring apparatus.

The above-described light transmittance is a transmittance for light having a wavelength of 500 nm. The above-described light transmittance is measured by a spectrophotometer, and specifically, is measured, for example, by a spectrophotometer U3310 (device name) manufactured by Hitachi, Ltd.

As a more specific measurement method, an aqueous dispersion liquid in which the content of the abrasive grains is adjusted to 1.0% by mass is prepared as a measurement sample. About 4 mL of this measurement sample is place in a cell having a size of 1 cm×1 cm, the cell is set in the device, and measurement is performed.

The abrasive grains including the hydroxide of a tetravalent metal element provide an absorbance of 1.00 or higher for light having a wavelength of 400 nm in an aqueous dispersion liquid in which the content of the abrasive grains is adjusted to 1.0% by mass, and thus the polishing rate for a material to be removed (for example, an insulating material) can be further improved. The reasons for this are not necessarily clearly known; however, it is considered that depending on the production conditions for the hydroxide of a tetravalent metal element, or the like, particles represented by composition formula: M(OH)ₐX_{b} (wherein a+b×c=4) having one to three hydroxide ions (OH⁻), and one to three anions (X^{c-}) with respect to one tetravalent metal (M⁴⁺) are produced as some of the abrasive grains (note that, such particles are also “abrasive grains including a hydroxide of a tetravalent metal element”). It is considered that, in M(OH)ₐX_{b}, an electron-withdrawing anion (X^{c-}) acts so that the reactivity of hydroxide ion is enhanced, and the polishing rate is improved along with an increase in the abundance of M(OH)ₐX_{b}. Furthermore, it is considered that, since particles represented by composition formula: M(OH)ₐX_{b} absorbs light having a wavelength of 400 nm, the polishing rate is improved along with an increase in the abundance of M(OH)ₐX_{b} for increasing the absorbance for light having a wavelength of 400 nm.

It is considered that the abrasive grains including the hydroxide of a tetravalent metal element may include not only particles represented by composition formula: M(OH)ₐX_{b} but also particles represented by composition formulas: M(OH)₄, MO₂, and the like. Examples of the anion (X^{c-}) include NO₃⁻ and SO₄²⁻.

Note that, whether the abrasive grains have composition formula: M(OH)ₐX_{b} can be checked by a method of thoroughly washing the abrasive grains with pure water and then detecting peaks corresponding to the anion (X^{c-}) by using an FT-IR ATR method (Fourier Transform Infra Red Spectrometer Attenuated Total Reflection method). The presence of the anion (X^{c-}) can also be checked by an XPS method (X-ray Photoelectron Spectroscopy). From X-ray absorption fine structure (XAFS) measurement, the existence of bonding of M and the anion (X^{c-}) can also be checked by performing EXAFS analysis.

Here, it has been confirmed that an absorption peak at a wavelength of 400 nm of M(OH)ₐX_{b} (for example, M(OH)₃X) is much smaller than the below-mentioned absorption peak at a wavelength of 290 nm. In this regard, in the case of using abrasive grains that provide an absorbance of 1.00 or higher for light having a wavelength of 400 nm in an aqueous dispersion liquid having a content of the abrasive grains of 1.0% by mass, which has a relatively large content of abrasive grains and whose absorbance is likely to be detected to be high, an effect of improving the polishing rate for a material to be removed (for example, an insulating material) is excellent.

The absorbance for light having a wavelength of 400 nm is preferably 1.00 or higher, more preferably 1.20 or higher, even more preferably 1.40 or higher, particularly preferably 1.50 or higher, extremely preferably 1.80 or higher, and highly preferably 2.00 or higher, from the viewpoint of obtaining a further excellent polishing rate for a material to be removed (for example, an insulating material).

The abrasive grains including the hydroxide of a tetravalent metal element provide an absorbance of 1.000 or higher for light having a wavelength of 290 nm in an aqueous dispersion liquid in which the content of the abrasive grains is adjusted to 0.0065% by mass, and thus the polishing rate for a material to be removed (for example, an insulating material) can be further improved. The reasons for this are not necessarily clearly known; however, particles represented by composition formula: M(OH)ₐX_{b} (for example, M(OH)₃X), which are produced depending on the production conditions for the hydroxide of a tetravalent metal element, or the like, have an absorption peak near the wavelength of 290 nm according to calculations, and for example, particles composed of Ce⁴⁺(OH⁻)₃NO₃⁻ have an absorption peak at a wavelength of 290 nm. Therefore, it is considered that, as the abundance of M(OH)ₐX_{b} increases and thereby the absorbance for light having a wavelength of 290 nm increases, the polishing rate is improved.

Here, the absorbance for light having a wavelength of about 290 nm tends to be detected to a greater degree as the measuring limit is exceeded. In this regard, in the case of using abrasive grains that provide an absorbance of 1.000 or higher for light having a wavelength of 290 nm in an aqueous dispersion liquid having a content of the abrasive grains of 0.0065% by mass, which has a relatively small content of abrasive grains and whose absorbance is likely to be detected to be low, an effect of improving the polishing rate for a material to be removed (for example, an insulating material) is excellent.

The absorbance for light having a wavelength of 290 nm is preferably 1.000 or higher, more preferably 1.050 or higher, even more preferably 1.100 or higher, particularly preferably 1.150 or higher, and extremely preferably 1.190 or higher, from the viewpoint of polishing a material to be removed at a further excellent polishing rate. The absorbance for light having a wavelength of 290 nm is preferably 10.000 or less.

In a case where the abrasive grains, which provide an absorbance of 1.00 or higher for light having a wavelength of 400 nm, provide an absorbance of 1.000 or higher for light having a wavelength of 290 nm in an aqueous dispersion liquid in which the content of the abrasive grains is adjusted to 0.0065% by mass, a material to be removed can be polished at a further excellent polishing rate.

The hydroxide of a tetravalent metal element (for example, M(OH)aXb) tends not to absorb light having a wavelength of 450 nm or higher, particularly, a wavelength of 450 to 600 nm. Therefore, from the viewpoint of suppressing adverse influence on polishing as a result of containing impurities, and thereby polishing a material to be removed at a further excellent polishing rate, it is preferable that the abrasive grains provide an absorbance of 0.010 or lower for light having a wavelength of 450 to 600 nm in an aqueous dispersion liquid in which the content of the abrasive grains is adjusted to 0.0065% by mass (65 ppm). That is, it is preferable that the absorbance for entire light in a wavelength range of 450 to 600 nm in an aqueous dispersion liquid in which the content of the abrasive grains is adjusted to 0.0065% by mass does not exceed 0.010. The lower limit of the absorbance for light having a wavelength of 450 to 600 nm is preferably 0.

The absorbance in an aqueous dispersion liquid can be measured using, for example, a spectrophotometer (device name: U3310) manufactured by Hitachi, Ltd. Specifically, for example, an aqueous dispersion liquid in which the content of the abrasive grains is adjusted to 1.0% by mass or 0.0065% by mass is prepared as a measurement sample. About 4 mL of this measurement sample is placed in a 1-cm square cell, and the cell is installed in the device. Next, measurement of the absorbance is performed in a wavelength range of 200 to 600 nm, and the absorbance is determined from a chart thus obtained.

The absorbance and light transmittance that are provided in the aqueous dispersion liquid by the abrasive grains can be measured by removing solid components other than the abrasive grains and liquid components other than water, subsequently preparing an aqueous dispersion liquid having a predetermined content of the abrasive grains, and performing measurement using this aqueous dispersion liquid. For removing the solid components or the liquid components, although varying depending on components contained in the polishing liquid, a centrifugation method such as centrifugal separation using a centrifuge that can apply a gravitational acceleration of several thousand G or less, or super-centrifugal separation using a super-centrifuge that can apply a gravitational acceleration of several ten thousand G or more; a chromatographic method such as partition chromatography, adsorption chromatography, gel permeation chromatography, or ion exchange chromatography; a filtration method such as natural filtration, filtration under reduced pressure, pressure filtration, or ultrafiltration; a distillation method such as distillation under reduced pressure or distillation under normal pressure; or the like can be used, and these may also be used in combination as appropriate.

Examples of methods in a case where the polishing liquid contains a compound having a weight average molecular weight of several ten thousands or more (for example, 50000 or more) include a chromatographic method and a filtration method, and gel permeation chromatography or ultrafiltration is preferred. In the case of using a filtration method, the abrasive grains contained in the polishing liquid can be passed through a filter by setting appropriate conditions. Examples of methods in a case where the polishing liquid contains a compound having a weight average molecular weight of several ten thousands or less (for example, less than 50000) include a chromatographic method, a filtration method, and a distillation method, and gel permeation chromatography, ultrafiltration, or distillation under reduced pressure is preferred. Examples of methods in a case where abrasive grains other than the abrasive grains including the hydroxide of a tetravalent metal element are contained in the polishing liquid include a filtration method and a centrifugation method, and the abrasive grains including the hydroxide of a tetravalent metal element are contained more in the filtrate in the case of filtration, while the abrasive grains including the hydroxide of a tetravalent metal element are contained more in the liquid phase in the case of centrifugal separation.

As a method for separating the abrasive grains by a chromatography method, for example, the abrasive grains and/or other components can be isolated by the following conditions.

Sample solution: 100 μL of polishing liquid

Detector: UV-VIS detector manufactured by Hitachi, Ltd., trade name: L-4200, wavelength: 400 nm

Integrator: GPC integrator manufactured by Hitachi, Ltd., trade name: D-2500

Pump: Manufactured by Hitachi, Ltd., trade name: L-7100

Column: Packing column for water-based HPLC manufactured by Hitachi Chemical Co., Ltd., trade name: GL-W550S

Eluent: Deionized water

Measurement temperature: 23° C.

Flow rate: 1 mL/min (pressure: about 40 to 50 kgf/cm² (3.9 to 4.9 MPa))

Measurement time: 60 minutes

Note that, a deaeration treatment of an eluent is preferably performed using a deaerator before performing chromatography. In a case where a deaerator cannot be used, an eluent is preferably deaeration-treated in advance with ultrasonic waves or the like.

Depending on the components contained in the polishing liquid, there is a possibility that the abrasive grains may not be isolated even under the above-described conditions; however, in that case, it is possible to separate the abrasive grains by optimizing the amount of the sample solution, the type of column, the type of eluent, the measurement temperature, the flow rate, and the like. There is a possibility that it is possible to separate the components from the abrasive grains by adjusting the pH of the polishing liquid to adjust the distillation time for the components contained in the polishing liquid. In a case where there are insoluble components in the polishing liquid, it is preferable to remove the insoluble components by filtration, centrifugal separation, and the like, as necessary.

The abrasive grains may include components (for example ceria, silica, alumina, zirconia, organic resin particles, and the like) other than the hydroxide of a tetravalent metal element, but the content of the hydroxide of a tetravalent metal element is preferably 80% by mass or more, more preferably 90% by mass or more, further preferably 95% by mass or more, particularly preferably 98% by mass or more, and extremely preferably 99% by mass or more, on the basis of the total mass of the abrasive grains. The abrasive grains are preferably composed of the hydroxide of a tetravalent metal element (substantially 100% by mass of the abrasive grains are the hydroxide of a tetravalent metal element) from the viewpoint that the polishing agent is easily prepared and the polishing properties are further excellent. Note that, the components other than the hydroxide of a tetravalent metal element may be contained in the abrasive grains as particles composed of the components other than the hydroxide of a tetravalent metal element, and may be contained in the abrasive grains as particles including the hydroxide of a tetravalent metal element and the components other than the hydroxide of a tetravalent metal element.

(Polymer)

The polymer includes a structure unit represented by Formula (1) above. The structure unit represented by Formula (1) above may be rephrased as a structure unit derived from vinylpyrrolidone. That is, the polymer may be a homopolymer of vinylpyrrolidone (polyvinylpyrrolidone) or a copolymer of vinylpyrrolidone and another copolymerization component.

The content of the structure unit represented by Formula (1) is preferably 0.00001% by mass or more, more preferably 0.0001% by mass or more, and further preferably 0.001% by mass or more, on the basis of the total mass of the polymer. When the content of the structure unit represented by Formula (1) is equal to or more than the lower limit value, there is a tendency that over-polishing of the stopper is further suppressed. The content of the structure unit represented by Formula (1) is preferably 10% by mass or less, more preferably 1% by mass or less, and further preferably 0.1% by mass or less, on the basis of the total mass of the polymer. When the content of the structure unit represented by Formula (1) is equal to or less than the upper limit value, there is a tendency that the polishing rate of silicon oxide (SiO₂) to be polished is less likely to decrease.

The polymer may further include a structure unit other than the structure unit represented by Formula (1). The structure unit other than the structure unit represented by Formula (1) is preferably a structure unit derived from a (meth)acrylic acid ester from the viewpoint of further suppressing over-polishing of the stopper. Here, the (meth)acrylic acid ester means an acrylic acid ester and a methacrylic acid ester.

From the viewpoint of further suppressing over-polishing of the stopper, the structure unit other than the structure unit represented by Formula (1) preferably has a cationic group (for example, a quaternary ammonium group). Examples of the counter anion of the cationic group include F⁻, Cl⁻, Br⁻, I⁻, CH₃COO⁻, CF₃COO⁻, CH₃SO₃⁻, CH₃CH₂SO₃⁻, CF₃SO₃⁻, C₆H₅SO₃⁻, CH₃C₆H₄SO₃⁻, HOSO₃⁻, and H₂PO₄⁻.

From the above-described viewpoint, the polymer more preferably includes a structure unit derived from a (meth)acrylic acid ester having a cationic group, and further preferably includes a structure unit represented by Formula (2) below.

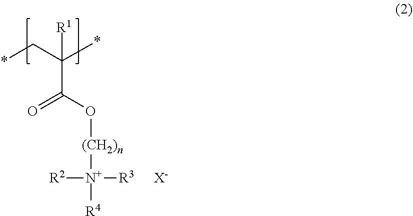

In Formula (2), R¹ represents a hydrogen atom or a methyl group, R² to R⁴ each independently represent a hydrocarbon group having 1 to 4 carbon atoms, n represents an integer of 1 or more and 4 or less, X⁻ represents a counter anion, and * represents a bonding hand.

As the structure unit represented by Formula (2), a structure unit in which R¹ to R³ are a methyl group, R⁴ is an ethyl group, and n is 2 in Formula (2) is preferred.

The polymer further including the structure unit derived from a (meth)acrylic acid ester may be obtained by polymerization of vinylpyrrolidone and a (meth)acrylic acid ester, and may be obtained by reacting a polymer obtained after polymerization of vinylpyrrolidone and a (meth)acrylic acid ester with another component. For example, the polymer further including the structure unit derived from a (meth)acrylic acid ester may be obtained by alkylating a tertiary amino group in a polymer obtained after polymerization of vinylpyrrolidone and a (meth)acrylic acid ester having a tertiary amino group. In other words, the polymer may be a quaternary ammonium salt including a quaternary ammonium group.

The content of the structure unit derived from a (meth)acrylic acid ester is preferably 20 to 80% by mass, more preferably 30 to 70% by mass, and further preferably 40 to 60% by mass, on the basis of the total mass of the polymer, from the viewpoint of further suppressing over-polishing of the stopper. In the present embodiment, the content of the structure unit represented by Formula (2) is preferably in the above range.

The weight average molecular weight of the polymer is preferably 50000 or more, more preferably 100000 or more, further preferably 300000 or more, particularly preferably 400000 or more, and extremely preferably 500000 or more, from the viewpoint of further suppressing over-polishing of the stopper. The weight average molecular weight of the polymer is preferably 5000000 or less, more preferably 3000000 or less, and further preferably 2000000 or less, from the viewpoint of a decrease in the polishing rate for silicon oxide (SiO₂) to be polished. From these viewpoints, the weight average molecular weight of the polymer is preferably 50000 to 5000000.

The weight average molecular weight can be measured, for example, by gel permeation chromatography (GPC) under the following conditions, using a calibration curve of standard polystyrene.

Instrument used: Hitachi L-6000 Model [manufactured by Hitachi, Ltd.]

Column: GELPACK GL-R420+GELPACK GL-R430+GELPACK GL-R440 [manufactured by Hitachi Chemical Co., Ltd., trade names, three in total]

Eluent: Tetrahydrofuran

Measurement temperature: 40° C.

Flow rate: 1.75 mL/min

Detector: L-3300RI [manufactured by Hitachi, Ltd.]

Preferred specific examples of the polymer include polyquaternium-11.

The content of the polymer is preferably 0.1 parts by mass or more, more preferably 0.5 parts by mass or more, further preferably 1 part by mass or more, particularly preferably 2 parts by mass or more, and extremely preferably 3 parts by mass or more, with respect to 100 parts by mass of the abrasive grains, from the viewpoint of further suppressing over-polishing of the stopper. The content of the polymer is preferably 20 parts by mass or less, more preferably 15 parts by mass or less, further preferably 10 parts by mass or less, and particularly preferably 7 parts by mass or less, with respect to 100 parts by mass of the abrasive grains, from the viewpoint of a decrease in the polishing rate for silicon oxide (SiO₂) to be polished. From these viewpoints, the content of the polymer is preferably 0.1 to 20 parts by mass with respect to 100 parts by mass of the abrasive grains.

(Liquid Medium)

The liquid medium is preferably water such as deionized water or ultrapure water. The content of the liquid medium may correspond to the remainder of the polishing liquid from which the contents of other constituent components are removed.

(Optional Additives)

The polishing liquid may further contain optional additives (excluding a compound corresponding to the above-described polymer) for the purpose of adjusting the polishing properties.

Examples of the optional additives include a polyoxyalkylene compound and a water-soluble polymer.

Examples of the polyoxyalkylene compound include a polyalkylene glycol and a polyoxyalkylene derivative.

Examples of the polyalkylene glycol include polyethylene glycol, polypropylene glycol, and polybutylene glycol. The polyalkylene glycol is preferably at least one selected from the group consisting of polyethylene glycol and polypropylene glycol, and is more preferably polyethylene glycol.

The polyoxyalkylene derivative is, for example, a compound obtained by introducing a functional group or a substituent into a polyalkylene glycol, or a compound obtained by adding a polyalkylene oxide to an organic compound. Examples of the functional group or the substituent include an alkyl ether group, an alkyl phenyl ether group, a phenyl ether group, a styrenated phenyl ether group, a glyceryl ether group, an alkylamine group, a fatty acid ester group, and a glycol ester group. Examples of the polyoxyalkylene derivative include a polyoxyethylene alkyl ether, a polyoxyethylene distyrenated phenyl ether (for example, manufactured by Kao Corporation, EMULGEN series), a polyoxyethylene alkyl phenyl ether (for example, manufactured by DKS Co. Ltd., NOIGEN EA series), a polyoxyalkylene polyglyceryl ether (for example, manufactured by Sakamoto Yakuhin Kogyo Co., Ltd., SC-E series and SC-P series), a polyoxyethylene sorbitan fatty acid ester (for example, manufactured by DKS Co. Ltd., SORGEN TW series), a polyoxyethylene fatty acid ester (for example, manufactured by Kao Corporation, EMANON series), a polyoxyethylene alkylamine (for example, manufactured by DKS Co. Ltd., AMIRADIN D), and other compounds having a polyalkylene oxide added thereto (for example, manufactured by Nissin Chemical Co., Ltd., SURFINOL 465, and manufactured by NIPPON NYUKAZAI CO., LTD., TMP series and BAP4-30H).

The weight average molecular weight of the polyoxyalkylene compound is preferably 100000 or less, more preferably 50000 or less, further preferably 20000 or less, particularly preferably 10000 or less, and extremely preferably 5000 or less, from the viewpoint of obtaining proper workability and foamability. The weight average molecular weight of the polyoxyalkylene compound is preferably 200 or more, more preferably 400 or more, further preferably 500 or more, particularly preferably 1000 or more, and extremely preferably 1500 or more, from the viewpoint of further improving polishing selectivity and flatness. Note that, the weight average molecular weight can be measured in the same manner as in the above-described polymer.

The content of the polyoxyalkylene compound is preferably 0.01% by mass or more, more preferably 0.02% by mass or more, further preferably 0.1% by mass or more, particularly preferably 0.3% by mass or more, extremely preferably 0.4% by mass or more, and highly preferably 0.5% by mass or more, on the basis of the total mass of the polishing liquid, from the viewpoint of further improving polishing selectivity and flatness. The content of the polyoxyalkylene compound is preferably 5% by mass or less, more preferably 2% by mass or less, and even more preferably 1% by mass or less, on the basis of the total mass of the polishing liquid, from the viewpoint of easily obtaining an adequate polishing rate. Note that, in a case where a plurality of compounds is used as the polyoxyalkylene compound, it is preferable that the total content of the respective compounds satisfies the above-described range.

The water-soluble polymer has the effect of adjusting polishing properties such as flatness, in-plane uniformity, the polishing selectivity of silicon oxide with respect to silicon nitride (the polishing rate for silicon oxide/the polishing rate for silicon nitride), and the polishing selectivity of silicon oxide with respect to polysilicon (the polishing rate for silicon oxide/the polishing rate for polysilicon). Here, the “water-soluble polymer” is defined as a polymer which is dissolved in 100 g of water in an amount of 0.1 g or more.

Examples of the water-soluble polymer include acrylic polymers such as polyacrylamide and polydimethylacrylamide; polysaccharides such as alginic acid, pectic acid, carboxymethyl cellulose, agar, curdlan, dextrin, cyclodextrin, and pullulan; vinyl-based polymers such as polyvinyl alcohol, polyvinylpyrrolidone, and polyacrolein; glycerin-based polymers such as polyglycerol and a polyglycerol derivative; and polyethylene glycol. The water-soluble polymer can be used singly or in combination of two or more kinds thereof.

In the case of using the water-soluble polymer, the content of the water-soluble polymer is preferably 0.0001% by mass or more, more preferably 0.001% by mass or more, further preferably 0.01% by mass or more, on the basis of the total mass of the polishing liquid, from the viewpoint of obtaining the addition effect of the water-soluble polymer while suppressing precipitation of the abrasive grains. The content of the water-soluble polymer is preferably 10% by mass or less, more preferably 5% by mass or less, further preferably 1% by mass or less, and particularly preferably 0.5% by mass or less, on the basis of the total mass of the polishing liquid, from the viewpoint of obtaining the addition effect of the water-soluble polymer while suppressing precipitation of the abrasive grains. In a case where a plurality of compounds is used as the water-soluble polymer, it is preferable that the total content of the respective compounds satisfies the above-described range.

The polishing liquid may further contain a cationic compound, carboxylic acid, amino acid, an oxidizing agent (for example, hydrogen peroxide), and the like, in addition to the above-described components.

(Properties of Polishing Liquid)

The pH of the polishing liquid is preferably 3.0 or more, more preferably 3.2 or more, and further preferably 3.5 or more, from the viewpoint of further improving the polishing rate for a material to be removed. The pH of the polishing liquid is preferably 5.0 or less, more preferably 4.7 or less, and further preferably 4.5 or less, from the viewpoint of further improving the polishing suppression effect of the stopper material. The pH of the polishing liquid is preferably 3.0 to 5.0 from the viewpoint that the storage stability of the polishing liquid and the polishing suppression effect of the stopper material are further excellent. The pH of the polishing liquid is defined as the pH at a liquid temperature of 25° C.

The pH of the polishing liquid can be adjusted by an acid component such as an inorganic acid or an organic acid; an alkali component such as ammonia, sodium hydroxide, tetramethylammonium hydroxide (TMAH), imidazole, or alkanolamine; or the like. In order to stabilize the pH, a buffering agent may be used, or a buffer solution (a solution containing a buffering agent) may be used. Examples of the buffer solution include an acetate buffer solution and a phthalate buffer solution.

The pH of the polishing liquid can be measured by a pH meter (for example, Model No. PHL-40 manufactured by Denki Kagaku Keiki Co., Ltd.). Specifically, for example, after performing 2-point calibration of the pH meter using a phthalate pH buffer solution (pH: 4.01) and a neutral phosphate pH buffer solution (pH: 6.86) as a standard buffer solution, an electrode of the pH meter is placed in the polishing liquid for 2 minutes or longer, and the value after stabilization is measured. The liquid temperature of both the standard buffer solution and the polishing liquid are set to 25° C.

(Storing Method)

The polishing liquid of the present embodiment is a one-pack type polishing liquid, and may be stored as a stock solution for a polishing liquid with a reduced liquid medium content during storage. This stock solution may be diluted with the liquid medium and then used during polishing.

<Polishing Liquid Set>

A polishing liquid set of an embodiment is a multi-pack type (for example, two-pack type) polishing liquid set containing constituent components of the polishing liquid of the embodiment described above divided into a first liquid (slurry) and a second liquid (additive liquid) so that the polishing liquid is obtained by mixing the first liquid and the second liquid. The polishing liquid set includes, for example, a first liquid containing the abrasive grains including a hydroxide of a tetravalent metal element and a liquid medium and a second liquid containing the polymer including a structure unit represented by Formula (1). The optional additives are preferably included in the second liquid among the first liquid and the second liquid. In the polishing liquid set, the first liquid and the second liquid are mixed immediately before polishing or during polishing to prepare the polishing liquid. The polishing rate can be adjusted by arbitrarily changing the blending of the first liquid and the second liquid. The polishing liquid set may be stored as a stock solution for a slurry and a stock solution for an additive liquid with a reduced liquid medium content. These stock solutions may be diluted with the liquid medium and then used during polishing.

<Polishing Method>

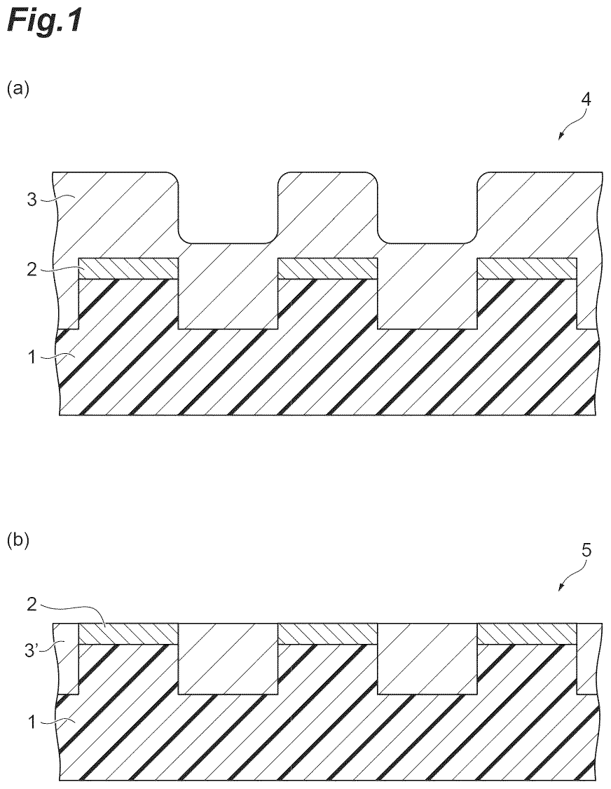

FIG. 1 is a schematic cross-sectional view illustrating a polishing method of an embodiment. The polishing method of the embodiment includes a step of preparing an article 4, the article 4 having a base material 1 having a concavo-convex pattern, a stopper 2 disposed on the convex portion of the base material 1 and containing silicon nitride, and a portion to be polished 3 disposed on the base material 1 and the stopper 2 to fill the concave portion of the base material 1 and containing silicon oxide, and a step of polishing a part of the portion to be polished 3 (at least a portion positioned on the stopper 2) by using the polishing liquid of the embodiment described above or a polishing liquid obtained by mixing the first liquid and the second liquid of the polishing liquid set of the embodiment described above. Note that, the portion to be polished 3 may be rephrased as an insulating portion.

Examples of the base material 1 include substrates used in production of semiconductor elements (for example, semiconductor substrates on which an STI pattern, a gate pattern, a wiring pattern, or the like is formed). The concavo-convex pattern is, for example, an L/S pattern. The pitch of L/S is, for example, 0.1 μm/0.1 μm or less.

The stopper 2 contains silicon nitride as a stopper material. The stopper 2 is formed, for example, using a stopper material containing silicon nitride. The content of silicon nitride in the stopper 2 is, for example, 90% by mass or more, and may be 95% by mass or more or 99% by mass or more. Elements (such as carbon and hydrogen) other than silicon and nitrogen may be contained in the stopper 2 for adjusting the quality of material.

The portion to be polished 3 contains silicon oxide as an insulating material. The portion to be polished 3 is formed, for example, using an insulating material containing silicon oxide. The content of silicon oxide in the portion to be polished 3 is, for example, 90% by mass or more, and may be 95% by mass or more or 99% by mass or more. A trace amount of boron (B), phosphorus (P), carbon (C), or the like may be contained in the portion to be polished 3 for enhancing the embedding property.

The stopper 2 and the portion to be polished 3 can be formed, for example, by CVD methods such as a low-pressure CVD method, a quasi-normal pressure CVD method, and a plasma CVD method; and a spin coating method of applying a liquid raw material to a rotating substrate.

Specifically, for example, the portion to be polished 3 containing silicon oxide is obtained, for example, by a method in which monosilane (SiH₄) and oxygen (O₂) are thermally reacted using a low-pressure CVD method, a method in which tetraethoxysilane (Si(OC₂H₅)₄) and ozone (O₃) are thermally reacted using a quasi-normal pressure CVD method, a method in which tetraethoxysilane and oxygen are subjected to a plasma reaction, a method in which a liquid raw material containing inorganic polysilazane, inorganic siloxane, or the like is applied onto a substrate using a spin coating method and a thermosetting reaction is conducted in furnace body or the like, and the like.

For example, the stopper containing silicon nitride can be formed by a low-pressure CVD method in which dichlorosilane and ammonia are thermally reacted, a plasma CVD method in which monosilane, ammonia, and nitrogen are subjected to a plasma reaction, and the like.

In a polishing step, a polishing apparatus can be used. Specifically, a general polishing apparatus, which has a holder that is capable of holding the article 4 and a polishing platen to which a polishing pad can be attached, can be used. A motor or the like in which the number of rotations can be changed is attached to each of the holder and the polishing platen. As the polishing apparatus, for example, a polishing apparatus: Reflexion manufactured by Applied Materials, Inc. can be used.

As the polishing pad, a general nonwoven fabric, a foamed body, a non-foamed body, and the like can be used. As the material for the polishing pad, it is possible to use a resin such as polyurethane, an acrylic resin, polyester, an acrylic-ester copolymer, polytetrafluoroethylene, polypropylene, polyethylene, poly-4-methylpentene, cellulose, cellulose ester, polyamide (for example, Nylon (trade name) and aramid), polyimide, polyimidamide, a polysiloxane copolymer, an oxirane compound, a phenolic resin, polystyrene, polycarbonate, or an epoxy resin. As the material for the polishing pad, particularly, at least one selected from the group consisting of foamed polyurethane and non-foamed polyurethane is preferred from the viewpoint of being further excellent in polishing rate and flatness. It is preferable that the polishing pad is subjected to grooving so that the polishing liquid is pooled.

In the polishing step, for example, while the portion to be polished 3 of the article 4 is pressed against a polishing pad (polishing cloth) of a polishing platen, the polishing liquid is supplied between the portion to be polished 3 and the polishing pad, and the article 4 and the polishing platen are relatively moved to polish the surface (surface to be polished) of the portion to be polished 3. By polishing the portion to be polished 3 and removing an excess region, irregularities on the surface of the article 4 are eliminated, and an article 5 after polishing having a smooth surface over the entire surface is obtained. The article 5 after polishing includes the base material 1, the stopper 2 disposed on the convex portion of the base material 1, and a remainder 3′ of the portion to be polished 3 disposed on the concave portion of the base material 1. Note that, in the polishing step, a part of the stopper 2 may be removed.

In the case of a one-pack type polishing liquid, as a method of supplying the polishing liquid onto the polishing platen, a method of supplying the polishing liquid by direct liquid conveyance; a method of conveying a stock solution for a polishing liquid and a liquid medium through separate pipings, merging them to mix, and then supplying; a method of mixing a stock solution for a polishing liquid and a liquid medium in advance and then supplying; and the like can be used.

In the case of performing polishing using a polishing liquid set, as a method of supplying the polishing liquid onto the polishing platen, the following methods are mentioned. For example, a method of conveying a slurry and an additive liquid through separate pipings, merging them to mix, and then supplying; a method of conveying a stock solution for a slurry, a stock solution for an additive liquid, and a liquid medium through separate pipings, merging them to mix, and then supplying; a method of mixing a slurry and an additive liquid in advance and then supplying; a method of mixing a stock solution for a slurry, a stock solution for an additive liquid, and a liquid medium in advance and then supplying; and the like can be used. A method of respectively supplying the slurry and the additive liquid of the polishing liquid set onto the polishing platen can also be used. In this case, a surface to be polished is polished using a polishing liquid that is obtained by mixing the slurry and the additive liquid on the polishing platen.

Polishing conditions are not limited, but the rotation speed of the polishing platen is preferably 200 min⁻¹ or less such that a semiconductor substrate is not let out, and the polishing pressure (processing load) to be applied to the semiconductor substrate is preferably 100 kPa or less from the viewpoint of sufficiently suppressing the generation of polishing scratches. The polishing liquid is preferably continuously supplied to the polishing pad with a pump or the like during polishing. The amount supplied for this is not limited, but it is preferable that the surface of the polishing pad is always covered with the polishing liquid.

The article after the completion of polishing is preferably thoroughly washed in running water to remove the particles adhering to the article. For the washing, dilute hydrofluoric acid or ammonia water may be concurrently used in addition to pure water, and a brush may be concurrently used to increase the washing efficiency. It is preferable that, after washing, the water droplets adhering to the article are removed off using a spin dryer or the like, and then the article is dried.

Hereinbefore, the polishing method of the present embodiment has been described, but the present invention is not limited to the above-described embodiment. For example, the polishing liquid and the polishing liquid set of the present embodiment can also be applied to materials other than silicon oxide. That is, the material to be removed may be a material other than the material containing silicon oxide. Examples of such a material include high permittivity materials such as Hf-based, Ti-based, and Ta-based oxides; semiconductor materials such as silicon, amorphous silicon, SiC, SiGe, Ge, GaN, GaP, GaAs, and organic semiconductors; phase-change materials such as GeSbTe; inorganic electroconductive materials such as ITO; and polymer resin materials such as polyimide-based, polybenzooxazole-based, acrylic, epoxy-based, and phenol-based materials. The stopper may be formed using a stopper material (such as polysilicon) other than the material containing silicon nitride. As the article to be polished, an article including a portion to be polished and not including a stopper may be used. The polishing liquid and the polishing liquid set of the present embodiment may be applied not only to film-shaped objects to be polished, but also to various types of substrates made of glass, silicon, SiC, SiGe, Ge, GaN, GaP, GaAs, sapphire, plastics, or the like.

The polishing liquid and the polishing liquid set of the present embodiment can be used not only for manufacturing of semiconductor elements, but also for manufacturing of image display devices such as TFTs or organic ELs; optical parts such as photomasks, lenses, prisms, optical fibers, or single crystal scintillators; optical elements such as optical switching elements or optical waveguides; light-emitting elements such as solid lasers or blue laser LEDs; and magnetic storage devices such as magnetic disks or magnetic heads.

### EXAMPLES

Hereinafter, the contents of the present invention will be more specifically described by means of Examples and Comparative Examples; however, the present invention is not limited to the following Examples.

<Synthesis of Hydroxide of Tetravalent Metal Element>

350 g of a 50% by mass Ce(NH₄)₂(NO₃)₆ aqueous solution (manufactured by Nihon Kagaku Sangyo Co., Ltd., trade name: CAN50 liquid) was mixed with 7825 g of pure water to obtain a solution. Next, while this solution was stirred, 750 g of an imidazole aqueous solution (10% by mass aqueous solution, 1.47 mol/L) was added dropwise thereto at a mixing rate of 5 mL/min, and thereby a precipitate containing cerium hydroxide was obtained. The cerium hydroxide was synthesized at a temperature of 25° C. and a stirring speed of 400 min⁻¹. The stirring was performed using a 3-blade pitch paddle with a total blade section length of 5 cm.

The obtained precipitate containing cerium hydroxide was subjected to centrifugal separation (4000 min⁻¹, for 5 minutes), and then subjected to solid-liquid separation with removal of a liquid phase by decantation. 10 g of particles obtained by solid-liquid separation and 990 g of water were mixed, and the particles were dispersed in the water by using an ultrasonic cleaner to prepare a cerium hydroxide slurry (content of particles: 1.0% by mass).

<Measurement of Average Particle Diameter>

When the average particle diameter of the abrasive grains (the abrasive grains including cerium hydroxide) in the cerium hydroxide slurry was measured using DelsaMax PRO (trade name) manufactured by Beckman Coulter, Inc., a value of 6 nm was obtained. The measurement method is as follows. First, about 0.5 mL of the polishing liquid (cerium hydroxide slurry, aqueous dispersion) was placed in a cell for measurement having a size of 12.5 mm×12.5 mm×45 mm (height) and then the cell was installed in the apparatus. Next, measurement was performed at 25° C. with the refractive index set to 1.333 and the viscosity set to 0.887 mPa-s as the measurement sample information.

<Structural Analysis of Abrasive Grains>

An appropriate amount of the cerium hydroxide slurry was collected and dried in a vacuum, and thereby the abrasive grains were isolated, and then, sufficient washing was performed with pure water to obtain a sample. For the sample thus obtained, measurement was performed according to an FT-IR ATR method, and a peak based on a nitrate ion (NO₃⁻) was observed in addition to a peak based on a hydroxide ion (OH⁻). Furthermore, when the same sample was measured by XPS (N-XPS) for nitrogen, a peak based on a nitrate ion was observed while no peak based on NH₄ was observed. From these results, it was confirmed that the abrasive grains included in the cerium hydroxide slurry include, at least in a portion, particles having a nitrate ion bonded to a cerium element. Furthermore, it was confirmed that since particles having a hydroxide ion bonded to the cerium element are included at least in a portion of the abrasive grains, the abrasive grains include cerium hydroxide. From these results, it was confirmed that the cerium hydroxide includes the hydroxide ion bonded to the cerium element.

<Measurement of Absorbance and Light Transmittance>

An appropriate amount of the cerium hydroxide slurry was collected and diluted with water so that the content of the abrasive grains reached 0.0065% by mass (65 ppm), and thus, a measurement sample (aqueous dispersion liquid) was obtained. About 4 mL of this measurement sample was placed in a 1-cm square cell, and the cell was installed in a spectrophotometer (device name: U3310) manufactured by Hitachi, Ltd. Measurement of the absorbance in a wavelength range of 200 to 600 nm was performed, and the absorbance for light having a wavelength of 290 nm and the absorbance for a light having a wavelength of 450 to 600 nm were measured. The absorbance for light having a wavelength of 290 nm was 1.192, and the absorbance for light having a wavelength of 450 to 600 nm was less than 0.010.

About 4 mL of the cerium hydroxide slurry (content of particles: 1.0% by mass) was placed into a 1-cm square cell, and the cell was installed in a spectrophotometer (device name: U3310) manufactured by Hitachi, Ltd. Measurement of the absorbance in a wavelength range of 200 to 600 nm was performed, and the absorbance for light having a wavelength of 400 nm and the light transmittance for light having a wavelength of 500 nm were measured. The absorbance for light having a wavelength of 400 nm was 2.25, and the light transmittance for light having a wavelength of 500 nm was 92%/cm.

<Preparation of Polishing Liquid for CMP>

### Example 1

Polyglycerol (manufactured by Sakamoto Yakuhin Kogyo Co., Ltd., weight average molecular weight: 750), polyoxyethylene distyrenated phenyl ether (manufactured by Kao Corporation, trade name: Emulgen A-500, average number of moles of added oxyethylene units of polyoxyethylene: 50), polyquaternium-11 (“Polymer A” in Table 1, quaternary ammonium salt obtained from a copolymer of vinylpyrrolidone and dimethylaminoethyl methacrylate and diethyl sulfate, manufactured by OSAKA ORGANIC CHEMICAL INDUSTRY LTD., trade name: H.C. Polymer 2L, weight average molecular weight: 800000), and the above-described cerium hydroxide slurry were mixed, and the pH was adjusted using an acid and a base, thereby preparing a polishing liquid for CMP having a pH of 3.8. The blending amount of each component was adjusted so that the content (solid content amount, based on the total mass of the polishing liquid) of each component reached a value shown in Table 1.

The pH of the polishing liquid for CMP was evaluated under the following conditions.

Measurement temperature: 25±5° C.

Measurement apparatus: Model No. PHL-40 manufactured by Denki Kagaku Keiki Co., Ltd.

Measurement method: After performing 2-point calibration using a standard buffer solution (phthalate pH buffer solution, pH: 4.01 (25° C.); neutral phosphate pH buffer solution, pH: 6.86 (25° C.)), an electrode was placed in the polishing liquid for CMP for 2 minutes or longer, and pH after stabilization was measured with the measurement apparatus above.

### Example 2

A polishing liquid for CMP having a pH of 3.8 was prepared in the same manner as in Example 1, except that polyvinylpyrrolidone (“Polymer B” in Table 1, manufactured by DKS Co. Ltd., weight average molecular weight: 450000) was used instead of polyquaternium-11.

### Comparative Example 1

A polishing liquid for CMP having a pH of 3.8 was prepared in the same manner as in Example 1, except that polyquaternium-11 was not used.

### Comparative Example 2

A polishing liquid for CMP having a pH of 3.8 was prepared in the same manner as in Example 1, except that a polyoxyethylene polyoxypropylene block polymer of ethylenediamine (“Polymer C” in Table 1, manufactured by ADEKA Corporation, trade name: Pluronic TR-913R (“Pluronic” is the registered trademark)) was used instead of polyquaternium-11.

### Comparative Example 3

A polishing liquid for CMP having a pH of 3.8 was prepared in the same manner as in Example 1, except that polyoxyethylene polyoxypropylene glyceryl ether (“Polymer D” in Table 1, manufactured by AOKI OIL INDUSTRIAL Co., Ltd., trade name: GEP-10000, ethylene oxide/propylene oxide: 50/50, weight average molecular weight: 10000) was used instead of polyquaternium-11.

<Polishing Liquid Physical Property Evaluation>

(Particle Diameter Measurement of Abrasive Grains)

When the average particle diameter of the abrasive grains (the abrasive grains including cerium hydroxide) in the polishing liquids for CMP of Examples 1 and 2 and Comparative Examples 1 to 3 was measured under the following conditions, the average particle diameter was 6 nm in all Examples.

Measurement temperature: 25±5° C.

Measurement apparatus: trade name: Delsa Max PRO manufactured by Beckman Coulter, Inc.

Measurement method: About 0.5 mL of the polishing liquid for CMP was placed in a cell for measurement having a size of 12.5 mm×12.5 mm×45 mm (height) and the cell was installed in Delsa Max PRO. Measurement was performed with the refractive index set to 1.333 and the viscosity set to 0.887 mPa-s as the measurement sample information in Delsa Max PRO software, and the value displayed as the cumulant diameter was read off.

<Polishing Rate Evaluation of CMP>

A blanket wafer (a wafer not having a pattern formed thereon) that is a substrate to be polished was polished using the polishing liquids for CMP of Examples 1 and 2 and Comparative Examples 1 to 3 under the following polishing conditions.

### (Polishing Conditions of CMP)

Polishing apparatus: Reflexion (manufactured by Applied Materials, Inc.)
Flow rate of polishing liquid for CMP: 200 mL/min
Polishing pad: Foamed polyurethane resin having closed pores (manufactured by ROHM AND HAAS ELECTRONIC MATERIALS CMP INC., Model No. IC1010 A6)
Polishing pressure: 13.8 kPa (2.0 psi)
Relative speed between substrate and polishing platen: 100.5 m/min
Polishing time: 1 minute
Washing: After a CMP treatment, washing was performed with water while applying an ultrasonic wave, and then drying was performed with a spin dryer.

Specifically, first, a substrate having a silicon oxide film having a thickness of 1 μm formed on a silicon substrate by a plasma CVD method and a substrate having a silicon nitride film having a thickness of 0.2 μm formed on a silicon substrate were prepared as a blanket wafer.

Next, the substrate to be polished was polished under the above-described conditions and washed. As for the substrate to be polished, a film thickness difference of the film to be polished before and after polishing was determined using a light interference type film thickness measuring apparatus (manufactured by Filmetrics Japan, Inc., trade name: F80), and the polishing rate for the film to be polished (the silicon nitride film and the silicon oxide film) (the polishing rate of the silicon nitride film: SiNRR, and the polishing rate of the silicon oxide film: SiO₂RR) was determined by the following formula. The results are shown in Table 1.

Polishing rate (RR)=[Film thickness difference (nm) of film to be polished before and after polishing]/[Polishing time (min)]

<Erosion Evaluation>

A pattern wafer (a pattern wafer having a simulated pattern formed thereon) that is a substrate to be polished was polished using the polishing liquids for CMP of Examples 1 and 2 and Comparative Examples 1 to 3 under the following polishing conditions.

### (Polishing Conditions of CMP)

Polishing apparatus: Reflexion (manufactured by Applied Materials, Inc.)
Flow rate of polishing liquid for CMP: 200 mL/min
Polishing pad: Foamed polyurethane resin having closed pores (manufactured by ROHM AND HAAS ELECTRONIC MATERIALS CMP INC., Model No. IC1010 A6)
Polishing pressure: 13.8 kPa (2.0 psi)
Relative speed between substrate and polishing platen: 100.5 m/min
Polishing time: The polishing time was adjusted so that the silicon oxide film on the convex portion was scrapped and over-polishing of 100 nm was further performed.

Specifically, the polishing time was determined by the following formula using the polishing rate (SiO₂RR) for the silicon oxide film determined in the above section “Polishing rate evaluation of CMP”.

Polishing time (min) for pattern wafer=[Film thickness (nm) of silicon oxide film on convex portion/Polishing rate (min/nm) of silicon oxide film]+[100 (nm)/Polishing rate (min/nm) of silicon oxide film]
Washing: After a CMP treatment, washing was performed with water while applying an ultrasonic wave, and then drying was performed with a spin dryer.

Specifically, first, AMT-STI MASK (diameter: 300 mm) manufactured by Advanced Materials Technology, INC. was prepared as a pattern wafer. This pattern wafer was a wafer obtained by laminating a silicon nitride film as a stopper film on a silicon substrate, then forming a trench in an exposure step, and laminating a silicon oxide film (SiO₂ film) as an insulating film on the silicon substrate and the silicon nitride film to fill the silicon nitride film and the trench. The silicon oxide film was formed by a HDP (High Density Plasma) method. A line (convex portion) and space (concave portion) had a narrow-pitch pattern portion having a pitch of 0.36 μm and a convex pattern density of 50%.

Here, the line and space is a simulated pattern, and is a pattern in which an Active portion (convex portion) masked by the silicon nitride film (stopper film) and a Trench portion (concave portion) with a groove formed are alternately arranged. For example, the phrase “a line and space having a pitch of 0.36 μm” means that the total of the widths of a line portion and a space portion is 0.36 μm. Furthermore, for example, the phrase “a line and space having a pitch of 0.36 μm and a convex pattern density of 50%” means a pattern in which a convex portion having a convex width of 0.18 μm and a concave portion having a concave width of 0.18 μm are alternately arranged. The size of the above-described pattern is 2.2 mm×2.2 mm, and four sides of the above-described pattern are surrounded by a convex pattern of 50 μm (50 μm pattern portion).

In the above-described pattern wafer, the film thickness of the silicon oxide film was 420 nm on each of the silicon substrate and the silicon nitride film. Specifically, the film thickness of the silicon nitride film on the silicon substrate was 130 nm, the film thickness of the convex portion of the silicon oxide film was 420 nm, the film thickness of the concave portion of the silicon oxide film was 420 nm, and the trench depth was 180 nm.

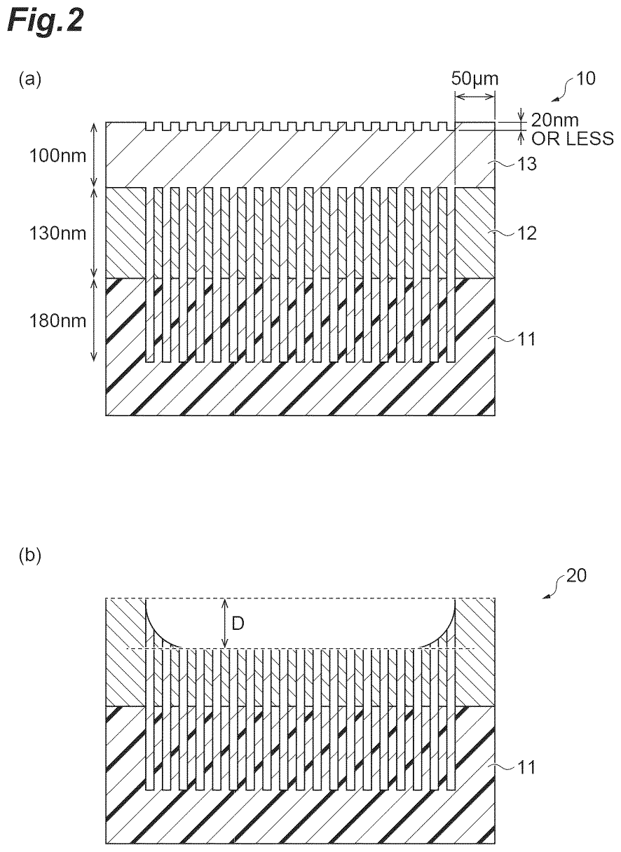

Next, a known polishing agent for CMP capable of obtaining self-stopping property (property for reducing the polishing rate in accordance with a decrease in the remaining step height in the simulated pattern) was used to polish the above-described pattern wafer until the remaining step height reached 100 nm or less. Specifically, the pattern wafer was polished until the thickness of the silicon oxide film on the convex portion in the portion having a pitch of 0.36 μm and a convex pattern density of 50% reached 100 nm, using a polishing agent in which HS-8005-D4 (trade name) manufactured by Hitachi Chemical Co., Ltd., HS-7303GP (trade name) manufactured by Hitachi Chemical Co., Ltd., and water were blended in a ratio of 2:1.2:6.8. Thereby, a substrate to be polished 10 illustrated in FIG. 2(a) was obtained. Note that, in FIG. 2, reference numeral 11 indicates a silicon substrate, reference numeral 12 indicates a silicon nitride film (stopper film), and reference numeral 13 indicates a silicon oxide film.

Next, the substrate to be polished was polished under the above-described conditions and washed to obtain a substrate 20 after polishing illustrated in FIG. 2(b). The two-dimensional irregular shape of the obtained substrate 20 was measured. Note that, in the measurement of the two-dimensional irregular shape, an automated atomic force profiler (manufactured by Bruker, trade name: InSight CAP) was used. From the result of the two-dimensional irregular shape measurement after polishing, a height difference D based on the silicon nitride film on the 50 μm pattern portion was regarded as erosion of the narrow-pitch pattern portion. The results are shown in Table 1.

TABLE 1

| | | | | | Comparative | Comparative | Comparative |
|---|---|---|---|---|---|---|---|
| | | Unit | Example 1 | Example 2 | Example 1 | Example 2 | Example 3 |
| Composition | Abrasive grains (cerium | % by mass | 0.05 | 0.05 | 0.05 | 0.05 | 0.05 |
| | hydroxide) | | | | | | |
| | Polyglycerol | % by mass | 0.5 | 0.5 | 0.5 | 0.5 | 0.5 |
| | Polyoxyethylene | % by mass | 0.01 | 0.01 | 0.01 | 0.01 | 0.01 |
| | distyrenated phenyl ether | | | | | | |
| | Polymer A | % by mass | 0.002 | — | — | — | — |
| | Polymer B | % by mass | — | 0.002 | — | — | — |
| | Polymer C | % by mass | — | — | — | 0.002 | — |
| | Polymer D | % by mass | — | — | — | — | 0.002 |
| Evaluation | SiO₂ polishing rate | nm/min | 150 | 150 | 190 | 190 | 210 |
| | SiN polishing rate | nm/min | 0.1 | 0.1 | 0.1 | 0.1 | 0.1 |
| | Polishing rate ratio | — | 1500 | 1500 | 1900 | 1900 | 2100 |
| | (SiO₂/SiN) | | | | | | |
| | Erosion | nm | 4.1 | 4.2 | 20.0 | 12.0 | 17.0 |

### REFERENCE SIGNS LIST

1: base material, 2: stopper, 3: portion to be polished, 4: article (before polishing), 5: article (after polishing).

1. A polishing liquid comprising:
abrasive grains comprising a hydroxide of a tetravalent metal element;
a polymer comprising a structure unit represented by Formula (1) below; and
a liquid medium. 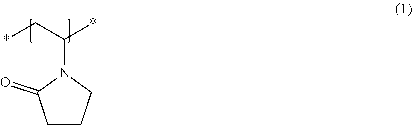
wherein, in Formula (1), * represents a bonding hand.

2. The polishing liquid according to claim 1, wherein the polymer further comprises a structure unit derived from a (meth)acrylic acid ester.

3. The polishing liquid according to claim 2, wherein the structure unit derived from a (meth)acrylic acid ester is a structure unit represented by Formula (2) below. 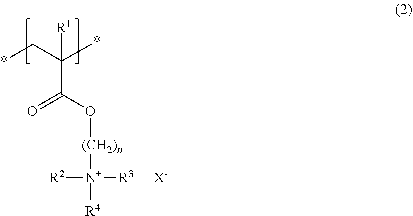
wherein, in Formula (2), R¹ represents a hydrogen atom or a methyl group, R² to R⁴ each independently represent a hydrocarbon group having 1 to 4 carbon atoms, n represents an integer of 1 or more and 4 or less, X⁻ represents a counter anion, and * represents a bonding hand.

4. The polishing liquid according to claim 1, wherein a weight average molecular weight of the polymer is 50000 or more.

5. The polishing liquid according to claim 1, wherein the hydroxide of a tetravalent metal element is cerium hydroxide.

6. The polishing liquid according to claim 1, wherein a pH is 3.0 to 5.0.

7. The polishing liquid according to claim 1, wherein the polishing liquid is used for selectively polishing silicon oxide with respect to silicon nitride.

8. A polishing liquid set comprising:
constituent components of the polishing liquid according to claim 1 separately stored as a first liquid and a second liquid, the first liquid containing the abrasive grains and a liquid medium, the second liquid containing the polymer and a liquid medium.

9. A polishing method comprising:
a step of preparing an article, the article having a base material having a concavo-convex pattern, a stopper disposed on the convex portion of the base material and containing silicon nitride, and a portion to be polished disposed on the base material and the stopper to fill the concave portion of the base material and containing silicon oxide; and
a step of polishing a part of the portion to be polished by using the polishing liquid according to claim 1.
